(19) United States
(12) Patent Application Publication
(10) Pub. No.: US 2026/0131698 A1
(43) Pub. Date: May 14, 2026

(54) NORMALITY MODELING AND ANOMALY DETECTION FOR ELECTRIFIED VEHICLE BATTERY SYSTEM

(71) Applicant: FCA US LLC, Auburn Hills, MI (US)

(72) Inventors: Jian Pei, Auburn Hills, MI (US); Ludmila Leborgne, Poissy (FR); Stephane Maurel, Poissy (FR)

(21) Appl. No.: 18/945,909

(22) Filed: Nov. 13, 2024

(51) Int. Cl. B60L 58/15; G01R 31/367

(52) U.S. Cl. CPC B60L 58/15; G01R 31/367

(57) ABSTRACT

A normality modeling and anomaly detection method for a high voltage battery system of an electrified vehicle includes obtaining a trained normality model configured to model a set of modeled parameters of the high voltage battery system based on a set of measured parameters of cells/modules of the high voltage battery system and a long short-term memory model, obtaining a trained anomaly classification model configured to determine a breakdown event of the high voltage battery system and a type of the breakdown event, detecting an anomaly condition for the high voltage battery system based on a comparison of the set of modeled parameters from the trained normality model and the set of measured parameters, and applying the trained anomaly classification model to the detected anomaly condition to determine a predicted breakdown event that will happen to the high voltage battery system and a type of the predicted breakdown event.

### FIELD

The present application generally relates to electrified vehicles, including hybrid electric vehicles (HEVs) and plug-in HEVs (PHEVs) and, more particularly, to techniques for normality modeling and anomaly detection for electrified vehicle battery systems.

### BACKGROUND

Many parameters of a battery system (e.g., a high voltage battery pack) of an electrified vehicle are not directly or easily measurable and thus are instead modeled using artificial intelligence (AI) and, more specifically, trained deep learning algorithms (e.g., neural networks). These models work well for nominal (normal) operating conditions or events, but there are also anomaly conditions or events, such as a quick or bulk charging phase of a vehicle. During these anomaly conditions or events, the battery system can experience a particular breakdown event, such as thermal runaway, state of charge (SOC) deviation, or temperature deviation. Conventional solutions detect anomaly conditions or events by training a model using a substantial amount of data from both healthy vehicles and breakdown vehicles (i.e., vehicles suffering breakdown events), but this would be time consuming and expensive. Accordingly, while such conventional battery system modeling techniques do work for their intended purpose, there exists an opportunity for improvement in the relevant art.

### SUMMARY

According to one example aspect of the invention, a normality modeling and anomaly detection system for a high voltage battery system of an electrified vehicle is presented. In one exemplary implementation, the system comprises a set of sensors configured to obtain a set of measured parameters of the high voltage battery system, wherein the high voltage battery system includes a plurality of battery cells and a control system configured to obtain a trained normality model configured to model a set of modeled parameters of the high voltage battery system based on the set of measured parameters and a long short-term memory (LSTM) model, obtain a trained anomaly classification model configured to determine a breakdown event of the high voltage battery system and a type of the breakdown event, detect an anomaly condition for the high voltage battery system based on a comparison of the set of modeled parameters from the trained normality model and the set of measured parameters, and apply the trained anomaly classification model to the detected anomaly condition to determine a predicted breakdown event that will happen to the high voltage battery system and a type of the predicted breakdown event.

In some implementations, the trained normality model is trained using only healthy vehicle data and not vehicle data from vehicles experiencing breakdown events. In some implementations, the healthy vehicle data is obtained from a set of fleet vehicles prior to a market launch of the electrified vehicle. In some implementations, the control system is further configured to output the predicted breakdown event/type to a customer associated with the electrified vehicle. In some implementations, the control system is configured to output the predicted breakdown event/type to a software application executing on a computing device associated with the customer.

In some implementations, the set of modeled parameters for the high voltage battery system includes a battery cell voltage and a battery cell temperature. In some implementations, the set of measured parameters for the high voltage battery system include charging current/intensity, air/ambient temperature, at least one of charge and state of charge (SOC) of the high voltage battery system and/or each battery cell. In some implementations, the anomaly condition corresponds to a bulk or quick charging phase of a charging period of the electrified vehicle.

According to another example aspect of the invention, a normality modeling and anomaly detection method for a high voltage battery system of an electrified vehicle is presented. In one exemplary implementation, the method comprises obtaining, by a control system of the electrified vehicle and from a set of sensors of the electrified vehicle, a set of measured parameters of the high voltage battery system, wherein the high voltage battery system includes a plurality of battery cells/modules, obtaining, by the control system, a trained normality model configured to model a set of modeled parameters of the high voltage battery system based on the set of measured parameters and an LSTM model, obtaining, by the control system, a trained anomaly classification model configured to determine a breakdown event of the high voltage battery system and a type of the breakdown event, detecting, by the control system, an anomaly condition for the high voltage battery system based on a comparison of the set of modeled parameters from the trained normality model and the set of measured parameters, and applying, by the control system, the trained anomaly classification model to the detected anomaly condition to determine a predicted breakdown event that will happen to the high voltage battery system and a type of the predicted breakdown event.

In some implementations, the trained normality model is trained using only healthy vehicle data and not vehicle data from vehicles experiencing breakdown events. In some implementations, the healthy vehicle data is obtained from a set of fleet vehicles prior to a market launch of the electrified vehicle. In some implementations, the method further comprises outputting, by the control system, the predicted breakdown event/type to a customer associated with the electrified vehicle. In some implementations, the outputting of the predicted breakdown event/type to the customer comprises outputting the predicted breakdown event/type to a software application executing on a computing device associated with the customer.

In some implementations, the set of modeled parameters for the high voltage battery system includes a battery cell voltage and a battery cell temperature. In some implementations, the set of measured parameters for the high voltage battery system include charging current/intensity, air/ambient temperature, at least one of charge and SOC of the high voltage battery system and/or each battery cell. In some implementations, the anomaly condition corresponds to a bulk or quick charging phase of a charging period of the electrified vehicle.

Further areas of applicability of the teachings of the present application will become apparent from the detailed description, claims and the drawings provided hereinafter, wherein like reference numerals refer to like features throughout the several views of the drawings. It should be understood that the detailed description, including disclosed embodiments and drawings referenced therein, are merely exemplary in nature intended for purposes of illustration only and are not intended to limit the scope of the present disclosure, its application or uses. Thus, variations that do not depart from the gist of the present application are intended to be within the scope of the present application.

### BRIEF DESCRIPTION OF THE DRAWINGS

FIG. 1 is a functional block diagram of an electrified vehicle having an example normality modeling and anomaly detection system according to the principles of the present application;

FIGS. 2A-2C are functional block diagrams of example system architectures for the normality modeling and anomaly detection system according to the principles of the present application; and

FIG. 3 is a flow diagram of an example normality modeling and anomaly detection method for an electrified vehicle according to the principles of the present application.

### DESCRIPTION

As previously discussed, many parameters of a battery system (e.g., a high voltage battery pack) of an electrified vehicle are not directly or easily measurable and thus are instead modeled using artificial intelligence (AI) and, more specifically, trained deep learning algorithms (e.g., neural networks). Some examples of these parameters include battery system state of charge (SOC), battery system state of health (SOH), battery module or cell voltage, and battery module or cell temperature. These models work well for nominal (normal) operating conditions or events, but there are also anomaly conditions or events, such as a quick or bulk charging phase of the vehicle. During these anomaly conditions or events, the battery system can experience a particular breakdown event, such as thermal runaway, SOC deviation, or temperature deviation. One conventional solution could detect anomaly conditions or events by training a complex model using a substantial amount of data from both healthy vehicles and breakdown vehicles (i.e., vehicles suffering breakdown events), but this would be time consuming and expensive. Accordingly, improved techniques for normality modeling and anomaly detection for a battery system of an electrified vehicle are presented herein.

The normality modeling of the present application uses a long short-term memory (LSTM) model, which is particularly useful for predicting battery cell voltage and temperature as discussed in greater detail below. Data is collected from customer/fleet vehicles and analyzed to remove noise and other unwanted data. The anomaly detection first defines a measurement for the level of anomaly, such as root-mean-square error (RMSE) or other relative error. A comparison of the predicted voltage/temperature values (from the LSTM) with actual values shows the level of anomaly. A simple classification model is then utilized to classify each detected anomaly as a particular type of breakdown event. The output of the classification model is if the battery system is in a normal charging session or an anomaly (e.g., quick/bulk charging) and, if an anomaly, which type of breakdown event the anomaly event belongs to. This classification model and the unique definition of the anomaly also provides for detection of previously unknown breakdown event types. Potential benefits include reduced costs and faster development of an accurate predictive maintenance application (e.g., before a production vehicle is launched or on market).

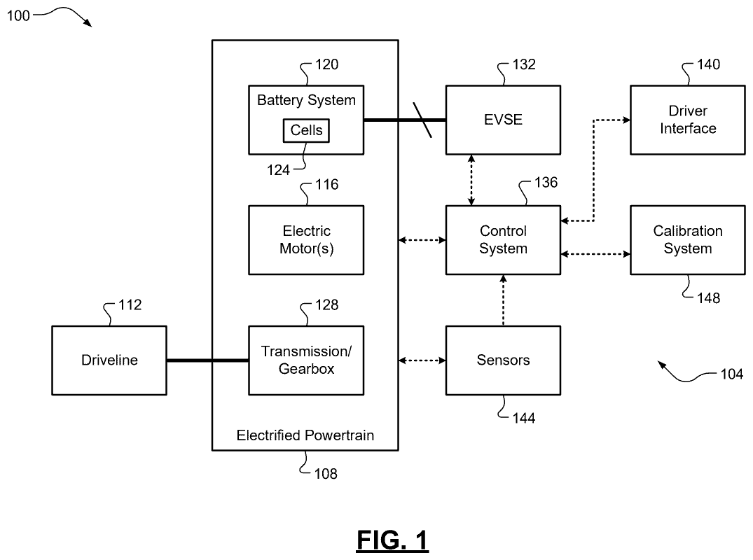

Referring now to FIG. 1, a functional block diagram of an electrified vehicle 100 having an example normality modeling and anomaly detection system 104 according to the principles of the present application is illustrated. The electrified vehicle 100 could be any suitable type of electrified vehicle, including a battery electric vehicle (BEV), a hybrid electric vehicle (HEV), or a plug-in HEV (PHEV). The electrified vehicle 100 generally comprises an electrified powertrain 108 that is configured to generate and transfer torque to a driveline 112 for propulsion. As shown, the electrified powertrain 108 includes at least one electric motor 116 (e.g., a three-phase traction motor and an inverter), a high voltage battery pack or system 120 (e.g., ˜400 or 800 VDC) comprising a plurality of battery modules or cells 124 (e.g., ˜96 or 198 lithium-ion type cells each being rated at ˜4.2 VDC), and a transmission or gearbox 128. The electric motor(s) 116 are powered by electrical energy output from the high voltage battery system 120, and the drive torque is transferred via the transmission or gearbox 128 to the driveline 112. It will be appreciated that the electrified powertrain 108 could further include other non-illustrated components, such as one or more secondary power sources (an internal combustion engine, a fuel cell system, etc.) and/or an auxiliary power module (APM) (e.g., a DC-DC converter).

The high voltage battery system 120 is rechargeable via electrified vehicle supply equipment (EVSE) 132, which could include a charging plug, a charging cable, and an external charging station. In some implementations, the external charging station could be a DC fast charging station and the EVSE 132 could be configured for DC fast charging (e.g., 400 or 800 VDC fast charging). A control system 136 controls operation of the electrified vehicle 100, including controlling the electrified powertrain 108 to generate a desired amount of drive torque to satisfy a driver torque request (e.g., from a driver interface 140, such as an accelerator pedal). The control system 136 can also be configured to control recharging of the high voltage battery system 120 via the EVSE 132. While a single control system 136 is shown, it will be appreciated that the control system 136 could include a plurality of different electronic control units (ECUs) or control modules, such as an supervisory controller (e.g., an electrified vehicle control unit, or EVCU), a charging controller (e.g., an integrated dual charging module, or IDCM, or an on-board charging module, or OBCM), and possible other sub-controllers or ECUs (e.g., a motor control processor, or MCP).

The charging process of the high voltage battery system 120 via the EVSE 132 generally comprises a quick or bulk charging phase (at a very high rate or current) followed by a trickle charging phase (at a much lower rate/current). The control system 136 is configured to receive measured parameters from a plurality of sensors 144 and is configured to perform the normality modeling and anomaly detection techniques of the present application. The plurality of sensors 144 are configured to measure various parameters of the electrified powertrain 108 and/or the EVSE 132, such as, but not limited to, operational state(s) of the electrified powertrain 108 and the EVSE 132, charging current/intensity, and air or ambient temperature. Some other parameters, such as SOC and SOH, are modeled or predicted (e.g., using a Kalman filter) based on other measured parameters (e.g., based on an equivalent circuit model for a battery cell). Two specific parameters that are being modeled or predicted as part of the nominal modeling of the present application are voltage of each battery cell 124 and temperature of each battery cell 124 or module (e.g., of multiple cells 124). In some implementations, at least some of the training aspects of the models described herein are performed offline by a separate calibration system 148 and then subsequently uploaded into the control system 136.

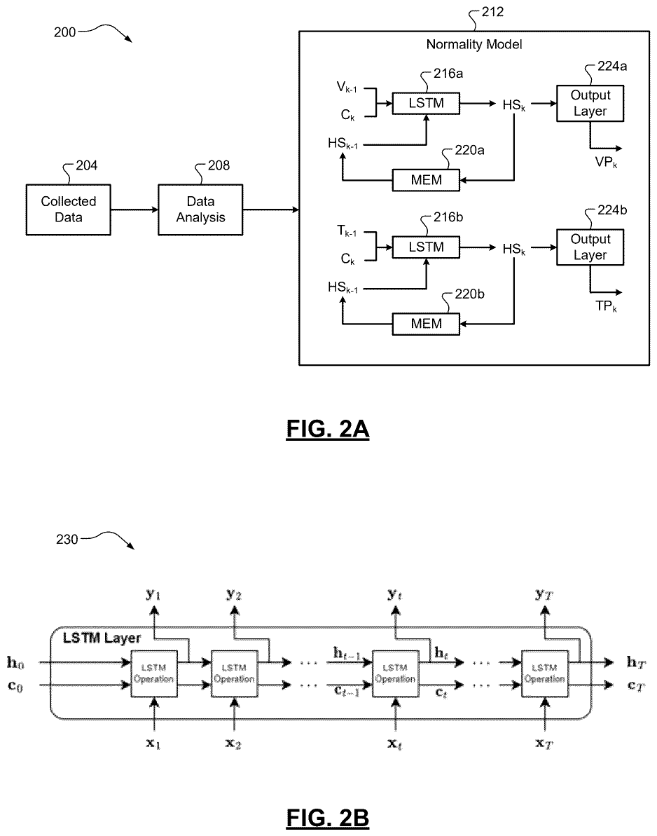

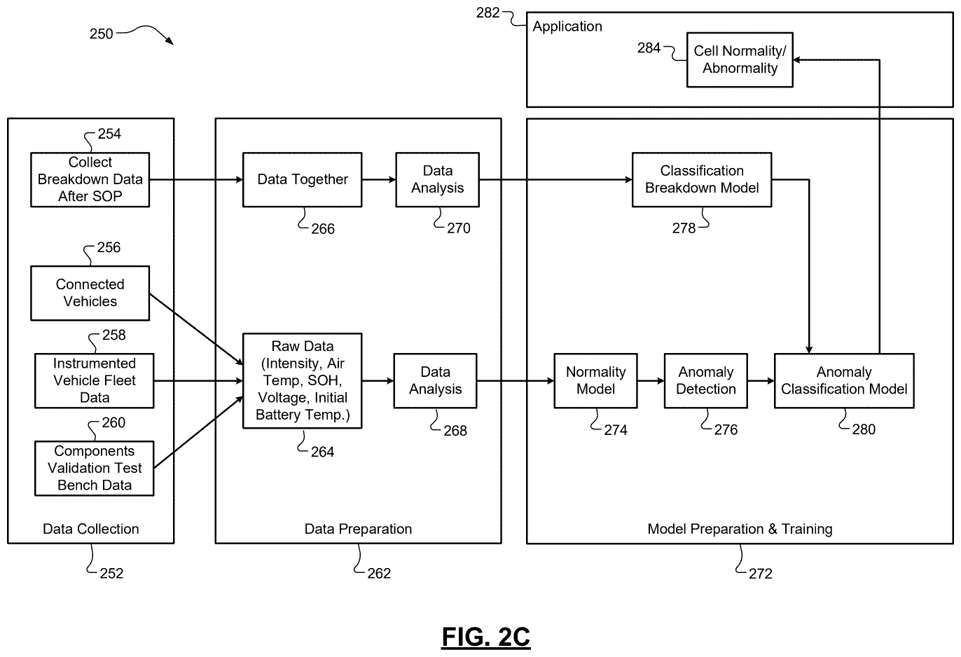

Referring now to FIGS. 2A-2C and with continued reference to FIG. 1, functional block diagrams of example system architectures 200, 220, 240 for the normality modeling and anomaly detection system 104 according to the principles of the present application is illustrated. In FIG. 2A, the normality model 212 (e.g., based on LSTM models 216a and 216b) has been trained with health vehicle data (collected data 204 that is subsequently analyzed at 208 to remove unwanted noise/signals) as following criteria (i)-(iv) and predicts (v) and (vi) as outputs: (i) charging current or intensity, (ii) SOC, (iii) charge, (iv) air or ambient temperature, (v) cell voltage, and (vi) model/cell temperature. The intent of the normality modeling is to predict battery cell/module temperature and cell voltage to predict future breakdown events. As shown, a previous measured or actual voltage Vₖ₋₁ and temperature Tₖ₋₁ and a corresponding control variables Cₖ, along with a previously-predicted hidden states HSₖ₋₁, are fed to a first and second LSTMs 216a and 216b, respectively, which each outputs a hidden state HSₖ.

These hidden states HSₖ are fed to both respective memories (MEM) 220a and 220b (and then returned and utilized for a subsequent prediction as HSₖ₋₁) and to respective output layers 224a and 224b. The outputs of the output layers are predicted voltage Vₖ and predicted temperature Tₖ of a particular battery cell/module k of the plurality of battery cells 124. While LSTM type models are specifically described herein due to their particular accuracy/applicability for cell voltage/temperature prediction, it will be appreciated that other types of models could also be utilized, such as, but not limited to, neural state-space (NSS) or Non-Linear AutoRegressive with eXogeneous variable (NLARX) deep learning algorithms or models. The normality model is first used to predict or detection each cells normal behavior in the charging phase, such as a cell normality voltage curve and a normality temperature curve, and then uses them as the standard to comparison with actual cell voltage and temperature (for anomaly detection).

LSTM models are used for sequence prediction, time series forecasting, natural language processing (NLP), and other tasks requiring learning long-term dependencies in sequential data. LSTM models can be employed in predicting battery behavior due to their ability to effectively model and learn from time-series data. That is, batteries exhibit dynamic changes in variables like voltage, current, and temperature over time, making LSTM models ideal for capturing intricate patterns and dependencies within such sequences. By training on historical data, LSTM models can forecast various aspects of battery performance such as SOC, remaining capacity, degradation trends, and anomalies. FIG. 2B depicts an example data flow 230 through an LSTM layer with input x and output y across T time steps. In the diagram, ht represents the output (also known as the hidden state) and ct represents the cell state at each time step t. If the layer outputs the full sequence, it produces y1, . . . , yT which corresponds to h1, . . . , hT. If the layer outputs only the final time step, it produces yT, which corresponds to hT. The number of channels in the output equals the number of hidden units in the LSTM layer.

In FIG. 2C, an example system architecture 250 for the entire normality modeling and anomaly detection system 104 is illustrated. In a data collection stage 252, breakdown data is collected at 254 (e.g., relative to a state of power, or SOP of the battery system 120). Quick or bulk charge data is also collected from connected vehicles at 256, from instrumented vehicle fleet data at 258, and from components validation bench data at 260. In a data preparation phase 262, the raw data from 256-260 is collected at 264. The collected raw data 264 could include, for example, charge current/intensity, air/ambient temperature, SOH, cell/module voltage, and initial battery/cell temperature. The collected raw data 264 and the collected breakdown data 254 are combined at 266 to form together data. Data analysis is then performed on the collected raw data 264 at 268 and on the together data 266 at 270. In a model preparation and training phase 272, the analyzed data 268 is provided to the normality model 274. This analyzed data 268 includes, for example, only healthy vehicle data (and not unhealthy vehicle data, such as when a healthy vehicle suffers from a breakdown event as previously described).

In parallel, the analyzed data 270 is provided to a classification breakdown model 278. This analyzed data 270 includes, for example, data with the different types of anomalies. After the normality modeling 274, the algorithm will predict cell voltage and temperature in bulk or quick charging phases and compare them with actual values to detect if anomalous behaviors happen at 276. For example, if battery temperature increases unusually, or any peak value happens, and so on. Or, if cell voltage doesn't increase as usual or its increase rate does not correct. If there are abnormal (anomaly) behaviors, the anomaly detection includes a breakdown classification model 278, which operates to classify a particular anomaly as a particular type of breakdown event (thermal runaway, SOC deviation, temperature deviation, etc.). In other words, the breakdown classification model 278 will recognize different kind of breakdowns, including breakdown events that were not previously known. For example, there could be two different sub-types of a particular known breakdown event. The detected anomaly or anomalies at 276 and their classifications from 278 are output to a final anomaly classification model 280, which is a trained machine learning model designed to detect and classify different types of anomalies. The output of this anomaly classification model 280 is then provided to a separate software application 282 (e.g., at a customer mobile phone or other computing device) and output as a predicted breakdown event/type 284.

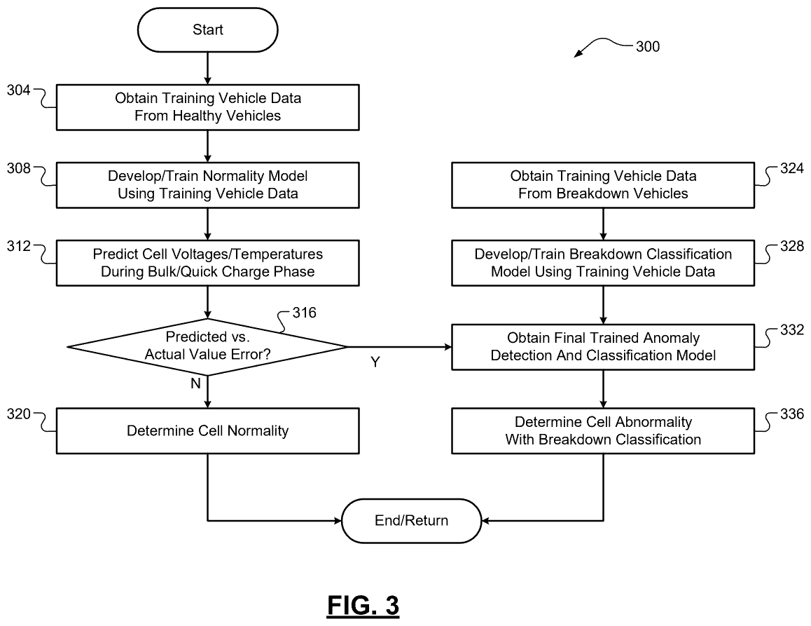

Referring now to FIG. 3 and with continued reference to the previous figures, a flow diagram of an example normality modeling and anomaly detection method 300 for a battery system of an electrified vehicle according to the principles of the present application is illustrated. While the method 300 specifically references the electrified vehicle 100 and its components for descriptive/illustrative purposes, it will be appreciated that the method 300 could be applicable to any suitably configured electrified vehicle. It will be appreciated that at least some aspects of the training phase could be executed offline by the calibration system 148. In a training phase (304-308), first training data (e.g., from healthy fleet vehicles only prior to market launch) is collected at 304 and a normality model (e.g., an LSTM based model) is developed and trained based on the first training data at 308. Also in the training phase (324-328), a breakdown classification model is developed using second training data (e.g., for fleet breakdown vehicles also prior to market launch or, also after the market launch) at parallel 324 and then a breakdown classification model is developed and trained using the second training data at parallel 328. In a usage phase (312-336), cell voltage/temperature values are predicted using the trained normality model at 312 and are then compared to actual (measured) values and a difference (error) therebetween is compared to one or more thresholds at 316.

When the error is zero or below the threshold(s), cell normality is detected at 320 and no further action needs to be taken and the method 300 ends or returns to 312. When the error is non-zero or exceeds the threshold(s) at 316, the method 300 proceeds to 332 where a final trained abnormality detection and classification model is obtained and utilized to detect cell abnormality with breakdown classification at 336. The method 300 then ends or returns to 312. Any predicted breakdown events and their types from 336 could be output to a customer application (mobile phone app, web-based app, etc.). The customer could then alter their driving plans (e.g., a current or future trip) based on the predicted breakdown events/types.

As briefly discussed above, in another aspect of the invention, a predictive maintenance algorithm is presented that incorporates the normality modeling and anomaly detection to predict (foresee) potential breakdown events that could cause malfunctions of the electrified vehicle 100 and thereafter potentially stand the driver. The predictive maintenance algorithm could be implemented, for example, as a software application that helps customers through predicting future breakdowns, giving the customer a snapshot of the journey based on the quick charging phase. The customer is smartly guided along his journey, notifying the future breakdown information by phone app. Real time updates are deployed relating to current, air temperature, battery temperature, battery SOC, and other factors that impact the prediction.

Broadly, an ideal normality modeling and anomaly detection could embody the following characteristics: (i) an effective normality modeling which predicts normal behavior, (ii) an anomaly detection software algorithm able to detect deviation between actual signal with the predicted value by the normality model, (iii) this prediction can be focused on specific use case, like cell voltage and temperature in quick charging phase, and (iv) a final notification or message will be sent to the customer by a mobile phone or device application or other suitable means, for notification of future breakdown events. Some of the factors that can impact customer trips include (i) SOC, (ii) SOH, (iii) current, (iv) total charging, (v) air temperature, (vi) battery initial temperature.

It will be appreciated that the terms “controller” and “control system” as used herein refer to any suitable control device or set of multiple control devices that is/are configured to perform at least a portion of the techniques of the present application. Non-limiting examples include an application-specific integrated circuit (ASIC), one or more processors and a non-transitory memory having instructions stored thereon that, when executed by the one or more processors, cause the controller to perform a set of operations corresponding to at least a portion of the techniques of the present application. The one or more processors could be either a single processor or two or more processors operating in a parallel or distributed architecture.

It should also be understood that the mixing and matching of features, elements, methodologies and/or functions between various examples may be expressly contemplated herein so that one skilled in the art would appreciate from the present teachings that features, elements and/or functions of one example may be incorporated into another example as appropriate, unless described otherwise above.

What is claimed is:

1. A normality modeling and anomaly detection system for a high voltage battery system of an electrified vehicle, the system comprising:
a set of sensors configured to obtain a set of measured parameters of the high voltage battery system, wherein the high voltage battery system includes a plurality of battery cells; and
a control system configured to:
obtain a trained normality model configured to model a set of modeled parameters of the high voltage battery system based on the set of measured parameters and a long short-term memory (LSTM) model;
obtain a trained anomaly classification model configured to determine a breakdown event of the high voltage battery system and a type of the breakdown event;
detect an anomaly condition for the high voltage battery system based on a comparison of the set of modeled parameters from the trained normality model and the set of measured parameters; and
apply the trained anomaly classification model to the detected anomaly condition to determine a predicted breakdown event that will happen to the high voltage battery system and a type of the predicted breakdown event.

2. The system of claim 1, wherein the trained normality model is trained using only healthy vehicle data and not vehicle data from vehicles experiencing breakdown events.

3. The system of claim 2, wherein the healthy vehicle data is obtained from a set of fleet vehicles prior to a market launch of the electrified vehicle.

4. The system of claim 1, wherein the control system is further configured to output the predicted breakdown event/type to a customer associated with the electrified vehicle.

5. The system of claim 4, wherein the control system is configured to output the predicted breakdown event/type to a software application executing on a computing device associated with the customer.

6. The system of claim 1, the set of modeled parameters for the high voltage battery system includes a battery cell voltage and a battery cell temperature.

7. The system of claim 6, wherein the set of measured parameters for the high voltage battery system include charging current/intensity, air/ambient temperature, at least one of charge and state of charge (SOC) of the high voltage battery system and/or each battery cell.

8. The system of claim 7, wherein the anomaly condition corresponds to a bulk or quick charging phase of a charging period of the electrified vehicle.

9. A normality modeling and anomaly detection method for a high voltage battery system of an electrified vehicle, the method comprising:
obtaining, by a control system of the electrified vehicle and from a set of sensors of the electrified vehicle, a set of measured parameters of the high voltage battery system, wherein the high voltage battery system includes a plurality of battery cells/modules;
obtaining, by the control system, a trained normality model configured to model a set of modeled parameters of the high voltage battery system based on the set of measured parameters and a long short-term memory (LSTM) model;
obtaining, by the control system, a trained anomaly classification model configured to determine a breakdown event of the high voltage battery system and a type of the breakdown event;
detecting, by the control system, an anomaly condition for the high voltage battery system based on a comparison of the set of modeled parameters from the trained normality model and the set of measured parameters; and
applying, by the control system, the trained anomaly classification model to the detected anomaly condition to determine a predicted breakdown event that will happen to the high voltage battery system and a type of the predicted breakdown event.

10. The method of claim 9, wherein the trained normality model is trained using only healthy vehicle data and not vehicle data from vehicles experiencing breakdown events.

11. The method of claim 10, wherein the healthy vehicle data is obtained from a set of fleet vehicles prior to a market launch of the electrified vehicle.

12. The method of claim 9, further comprising outputting, by the control system, the predicted breakdown event/type to a customer associated with the electrified vehicle.

13. The method of claim 12, wherein the outputting of the predicted breakdown event/type to the customer comprises outputting the predicted breakdown event/type to a software application executing on a computing device associated with the customer.

14. The method of claim 9, wherein the set of modeled parameters for the high voltage battery system includes a battery cell voltage and a battery cell temperature.

15. The method of claim 14, wherein the set of measured parameters for the high voltage battery system include charging current/intensity, air/ambient temperature, at least one of charge and state of charge (SOC) of the high voltage battery system and/or each battery cell.

16. The method of claim 15, wherein the anomaly condition corresponds to a bulk or quick charging phase of a charging period of the electrified vehicle.
